(19) United States
(12) Patent Application Publication
(10) Pub. No.: US 2025/0386695 A1
(43) Pub. Date: Dec. 18, 2025

(54) DISPLAY DEVICE

(71) Applicant: LG Display Co., Ltd., Seoul (KR)

(72) Inventor: DongHun JUNG, Paju-si (KR)

(73) Assignee: LG Display Co., Ltd., Seoul (KR)

(21) Appl. No.: 19/235,974

(22) Filed: Jun. 12, 2025

(30) Foreign Application Priority Data
Jun. 13, 2024 (KR) 10-2024-0076739

(51) Int. Cl. H10K 59/131; H10K 59/124

(52) U.S. Cl. CPC H10K 59/131; H10K 59/124

(57) ABSTRACT

A display device may include a substrate, a first metal on the substrate, a first insulation layer on the first metal, and a first metal pattern disposed on the first insulation layer, electrically connected to the first metal, and extending through an edge side surface of the first insulation layer to at least a partial area in the bending area. Examples of such a display device may prevent cracks.

### CROSS-REFERENCE TO RELATED APPLICATION

This application claims the benefit of and priority to Korean Patent Application No. 10-2024-0076739, filed on Jun. 13, 2024, the entire contents of which are incorporated herein by reference for all purposes as if fully set forth herein.

### BACKGROUND

### 1. Technical Field

Embodiments of the disclosure relate to a display device, and particularly to, for example, without limitation, a curable display device.

### 2. Description of Related Art

As the information society develops, demand for display devices for displaying images is increasing in various forms. Various display devices, such as liquid crystal display devices and organic light emitting display devices, are being utilized in recent years.

The display device may include a display panel, and a portion of the display panel may be bendable. The bending portion of the display panel may crack.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the disclosure may provide a display device capable of preventing cracks in a non-display area.

Embodiments of the disclosure may provide a display device capable of strengthening a bending area adjacent to a link area.

Embodiments of the disclosure may provide a display device capable of process optimization by preventing cracks that may occur in a process.

Embodiments of the disclosure may provide a display device comprising a first metal disposed on the substrate and positioned in the display area or positioned closer to the display area than the bending area in the non-display area, a first insulation layer disposed on the first metal and extending farther outside than the first metal, and a first metal pattern disposed on the first insulation layer, electrically connected to the first metal, and extending through an edge side surface of the first insulation layer to at least a partial area in the bending area.

Embodiments of the disclosure may provide a display device comprising a substrate, a display area, a non-display area positioned outside the display area and including a pad area and a bending area positioned closer to the display area than the pad area, a first insulation layer disposed on the substrate, a first metal pattern disposed on the first insulation layer and extending to at least a partial area in the bending area positioned farther outside than an edge of the first insulation layer, a second insulation layer disposed on the first metal pattern, and a line disposed on the second insulation layer and electrically connecting a pad in the pad area and the first metal pattern, wherein the second insulation layer may include a contact hole for electrically connecting the line and the first metal pattern, and wherein the contact hole may be positioned in the display area or positioned closer to the display area than the bending area in the non-display area.

The display device may further comprise a shield metal disposed in contact with the second gate metal in the bending area.

According to embodiments of the disclosure, there may be provided a display device capable of preventing cracks in a non-display area by disposing metals in a bending area adjacent to a link area.

According to embodiments of the disclosure, there may be provided a display device capable of strengthening a bending area adjacent to a link area by disposing metals in a bending area adjacent to a link area.

According to embodiments of the disclosure, there may be provided a display device capable of process optimization by preventing cracks that may occur in a process by disposing metals in a bending area adjacent to a link area.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view illustrating a system configuration of a display device according to embodiments of the disclosure;

FIG. 2 illustrates a display panel according to an embodiment of the disclosure;

FIG. 3 is a cross-sectional view illustrating a display panel according to embodiments of the disclosure;

FIG. 4 is a view illustrating a substrate of a display panel according to embodiments of the disclosure;

FIG. 5 is a cross-sectional view illustrating a bending area of a display device according to embodiments of the disclosure;

FIG. 6 is a plan view illustrating a first non-display area according to embodiments of the disclosure;

FIG. 7 is an enlarged view illustrating a partial area of the plan view of the display panel of FIG. 6;

FIG. 8 is a cross-sectional view of area A-B of FIG. 7 according to one embodiment of the disclosure;

FIG. 9 is a cross-sectional view of area A-B of FIG. 7 according to another embodiment of the disclosure; and

FIG. 10 is a cross-sectional view of area A-B of FIG. 7 according to still another embodiment of the disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting,” “make up of,” and “formed of” used herein are generally intended to allow other components to be added unless the terms are used with the term “only.” As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Terms, such as “first,” “second,” “A,” “B,” “(A),” or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but also a third element can be “interposed or disposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom,” “downward,” “upward,” “upper,” “lower,” and the like refer to an arbitrary frame of reference.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the disclosure are described in detail with reference to the accompanying drawings.

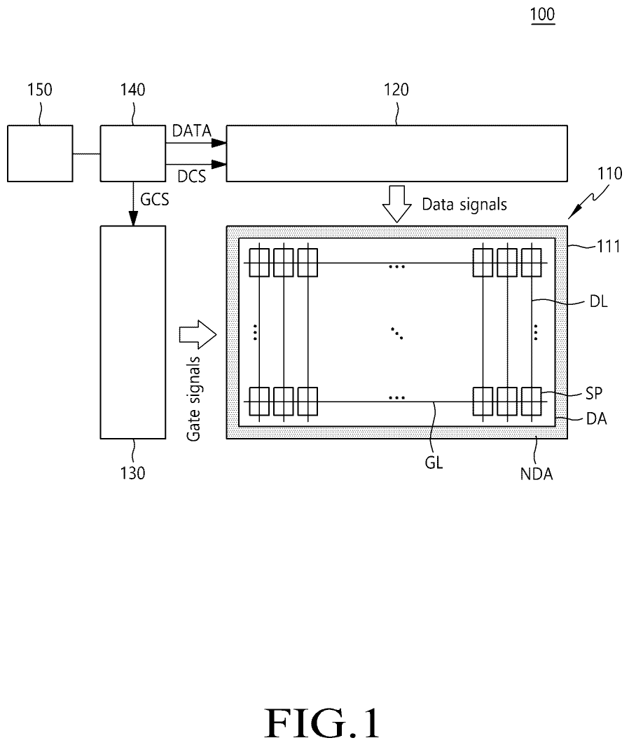

FIG. 1 illustrates a display device 100 according to embodiments of the disclosure.

Referring to FIG. 1, a display device 100 according to embodiments of the disclosure may include a display panel 110 and display driving circuits, among others, as components for displaying images. The display driving circuit may be a circuit for driving the display panel 110. The display driving circuits may include a data driving circuit 120, a gate driving circuit 130, and a controller 140, but embodiments of the disclosure are not limited thereto.

The display panel 110 may include a substrate 111 and a plurality of subpixels SP disposed on the substrate 111.

The substrate 111 may include a display area DA in which images may be displayed and a non-display area NDA in which no image is displayed.

The display area DA may also be referred to as an active area. A plurality of subpixels SP for image display may be disposed in the display area DA. The non-display area NDA may be an area outside the display area DA. The non-display area NDA may also be referred to as a bezel (or bezel area). The non-display area NDA may include a pad area positioned in for example, but not limited to a column direction from the display area DA.

For example, the non-display area NDA may include a first non-display area, a second non-display area, a third non-display area, and a fourth non-display area. The first non-display area may be positioned outside the display area DA in the column direction. The second non-display area may be positioned outside the display area DA in the row direction. The third non-display area may be positioned outside the display area DA in the column direction and may be positioned opposite to the first non-display area. The fourth non-display area may be positioned outside the display area DA in the row direction and may be positioned opposite to the second non-display area. The first non-display area among the first to fourth non-display areas may include a pad area where the data driving circuit is connected or bonded. Among the first to fourth non-display areas, the second to fourth non-display areas including no pad area may have a very small size, but embodiments of the disclosure are not limited thereto. Alternatively or additionally, a pad area may be included in one or more non-display areas.

As another example, the boundary area between the display area DA and the non-display area NDA may be bent so that the non-display area NDA may be positioned under the display area so as to reduce bezel area.

No or little change may be made to the non-display area NDA shown to the user when the user views the display device 100 from the front, but embodiments of the disclosure are not limited thereto. For example, no or little change may be made to the non-display area NDA shown to the user when the user views the display device 100 from other directions, such as from a side of the display device 100.

The display device 100 according to embodiments of the disclosure may be a self-luminous display device in which the display panel 110 emits light by itself or a liquid display device, but embodiments of the disclosure are not limited thereto. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic material-based (such as micromolecule luminescence materials, polymer luminescence materials, etc.) light emitting diode (OLED). As another example, the display device 100 according to embodiments of the disclosure may be an inorganic light emitting display device in which the light emitting element is implemented as an inorganic material-based (such GaN, GaAs, etc.) light emitting diode. As another example, the display device 100 according to embodiments of the disclosure may be a quantum dot display device in which the light emitting element is implemented as a quantum dot which is self-emission semiconductor crystal. As another example, the display device 100 according to embodiments of the disclosure may be a micro LED display device or a mini LED display device.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but embodiments of the disclosure are not limited thereto.

Various types of signal lines for driving a plurality of subpixels SP may be disposed on the substrate 111 of the display panel 110.

For example, various types of signal lines may include a plurality of data lines DL transferring data signals (also referred to as data voltages or image signals), a plurality of gate lines GL transferring gate signals (also referred to as scan signals), a plurality of power lines (also referred to as power supply lines) supplying various voltages such as VDD, VSS, a plurality of touch lines, etc.

The plurality of data lines DL and the plurality of gate lines GL may cross each other. Each of the plurality of data lines DL may be disposed to extend in the column direction. Each of the plurality of gate lines GL may be disposed to extend in the row direction. According to embodiments of the disclosure, the column direction and the row direction may be relative directions. In other words, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the row direction and the column direction may be 90 degrees or may an angle different from 90 degrees. Further, in embodiments of the disclosure, the row direction may be referred to as a first direction, and the column direction may be referred to as a second direction.

The data driving circuit 120 may be a circuit for driving the plurality of data lines DL, and may out data signals to the plurality of data lines DL.

The data driving circuit 120 may receive digital image data DATA from the controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on voltage and a second gate voltage corresponding to a turn-off voltage together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the display device 100 according to embodiments of the disclosure, the gate driving circuit 130 may be embedded, in a gate in panel (GIP) type, in the display panel 110, but embodiments of the disclosure are not limited thereto. When the gate driving circuit 130 is of the gate in panel type, the gate driving circuit 130 may be formed on the substrate 111 of the display panel 110 during the manufacturing process of the display panel 110.

For example, the gate driving circuit 130 may be disposed in the non-active area NDA of the display panel 110.

As another example, the gate driving circuit 130 may be disposed in the display area DA of the display panel 110. For example, the gate driving circuit 130 may be disposed in a first partial area in the display area DA (e.g., a left area or a right area or an upper or lower area in the display area DA). As another example, the gate driving circuit 130 may be disposed in a first partial area in the display area DA (e.g., a left area or right area or an upper or lower area in the display area DA) and a second partial area (e.g., a right area or left area or a lower or upper area in the display area DA). As another example, the gate driving circuit 130 may be disposed over the entire display area DA.

When the gate driving circuit 130 is disposed in the display area DA of the display panel 110, the gate driving circuit 130 may vertically overlap the subpixels SP disposed in the display area DA to increase an aperture ratio. More specifically, the gate driving circuit 130 may vertically overlap the light emitting elements and transistors included in the disposed subpixels SP in the display area DA. The gate driving circuit 130 may vertically overlap a plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be identical. As another example, the first semiconductor material and the second semiconductor material may be different from each other. For example, the first semiconductor material may be a silicon-based semiconductor material (e.g., low temperature polysilicon), and the second semiconductor material may be an oxide semiconductor material.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), DSP (Digital Signal Processor), DSPD (Digital Signal Processing Device), PLD (Programmable Logic Device), micro controller, mini-computer, or a processor including a mobile processor, an application processor, a micro-processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI) interface, a mini-LVDS interface, an reduced swing differential signaling (RSDS) interface, a time minimized differential signaling (TDMS) and a serial peripheral interface (SPI), but embodiments of the disclosure are not limited thereto.

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, and/or the position of the touch.

The touch sensing circuit may include a touch driving circuit that drives and senses the touch sensor and generates and outputs touch sensing data and a touch controller that may detect an occurrence of a touch and/or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch sensor, in the form of a touch panel, exists outside the display panel 110, the touch panel is of an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate 111, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device. Alternatively, the touch driving circuit and the gate driving circuit may be implemented as separate devices or as a single device.

The display device 100 may further include a power supply circuit for supplying various types of power to the display driver integrated circuit and/or the touch sensing circuit. The power supply circuit may supply various voltages and power voltages related to various driving such as display driving, touch driving, etc. to the display driving circuit or other components of display panel 110.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays, but embodiments of the disclosure are not limited thereto.

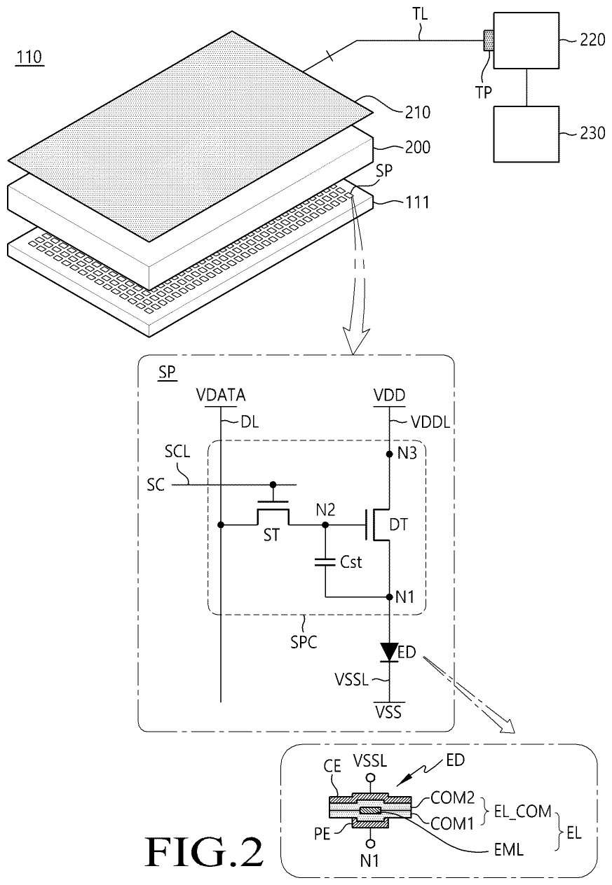

FIG. 2 illustrates a display panel 110 according to an embodiment of the disclosure.

Referring to FIG. 2, the display panel 110 may include a substrate 111 disposed in a plurality of subpixels SP and an encapsulation layer 200 on the substrate 111. The encapsulation layer 200 may also be referred to as an encapsulation substrate or an encapsulation unit.

Referring to FIG. 2, when the display device 100 according to embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but embodiments of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP. The common intermediate layer EL_COM may be commonly disposed across the plurality of subpixels SP, but embodiments of the disclosure are not limited thereto.

The light emitting layer EML may be disposed for each emission area. The common intermediate layer EL_COM may be commonly disposed across a plurality of emission areas and non-emission areas, but embodiments of the disclosure are not limited thereto. For example, some of above layers may be omitted or combined.

For example, the first common intermediate layer COM1 may include a hole injection layer HIL, an electron blocking layer EBL, and a hole transport layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

The hole injection layer may inject holes from the pixel electrode PE to the hole transport layer, the hole transport layer may transport the holes to the light emitting layer EML, the electron injection layer may inject electrons from the common electrode CE to the electron transport layer, and the electron transport layer may transport electrons to the light emitting layer EML. The electrons and the holes may be recombined in the light emitting layer EML to emit light.

For example, the common electrode CE may be electrically connected to the base voltage line VSSL. The base voltage VSS, which is one type of the common pixel driving voltage, may be applied to the common electrode CE through the base voltage line VSSL. The pixel electrode PE may be electrically connected directly or indirectly (through another transistor) to the first node N1 of the driving transistor DT of each subpixel SP. In the disclosure, “base voltage VSS” may also be referred to as a “low-potential power voltage” or a “low-potential voltage,” and “base voltage line VSSL” may also be referred to as a “low-potential power voltage line” or a “low-potential voltage line.”

Each light emitting element ED may include portions where the pixel electrode PE, the light emitting layer in the intermediate layer LE, and the common electrode CE overlap. A predetermined light emitting area may be formed by each light emitting element ED. For example, the light emitting area of each light emitting element ED may include an overlapping area of the pixel electrode PE, the intermediate layer EL, and the common electrode CE.

For example, the light emitting element ED may be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1, a second node N2, and a third node N3. The first node N1 may be electrically connected to the light emitting element ED, the second node N2 may receive a data signal VDATA, and the third node N3 may receive a driving voltage VDD from the driving voltage line VDDL. The driving transistor DT may be connected to the first node N1 and the third node N3.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node, the first node N1 may be a source node, and the third node N3 may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT, but embodiments of the disclosure are not limited thereto.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. Accordingly, the area of the emission area may increase and the aperture ratio may increase.

When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common pixel driving voltages supplied to the subpixel SP may vary according to the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110 to cover light emitting elements. The encapsulation layer 200 may prevent external moisture or oxygen from penetrating into circuit elements (e.g., the light emitting element ED). The encapsulation layer 200 may also extend to the bezel area. The encapsulation layer 200 may be configured in various forms so that the light emitting elements ED do not contact foreign matters such as moisture or oxygen. For example, the encapsulation layer 200 may be constituted of two or more layers in which organic films and inorganic films are alternately stacked, but embodiments of the disclosure are not limited thereto. For example, the encapsulating unit 200 may have a structure in which at least one organic encapsulating layer is disposed between two inorganic encapsulating layers.

Referring to FIG. 2, a display device 100 according to embodiments of the disclosure may include a touch sensor layer 210 including a plurality of sensor electrodes to sense the user's touch, a touch driving circuit 220 configured to sense the plurality of sensor electrodes, and a touch controller 230 configured to determine the presence or absence of a touch and/or touch coordinates using the sensing result (touch sensing data) of the touch driving circuit 220. A touch sensor may be a pixel electrode itself or may be connected to a pixel electrode.

The touch sensor layer 210 may be embedded in the display panel 110. For example, the touch sensor layer 210 may be disposed on the encapsulation layer 200 in the display panel 110. The touch sensor layer 210 may be a touch unit.

The display panel 110 may further include a plurality of touch pads TP electrically connected to the touch driving circuit 220 and a plurality of touch routing lines (“touch lines”) for electrically connecting the plurality of sensor electrodes included in the touch sensor layer 210 to the plurality of touch pads TP connected to the touch driving circuit 220.

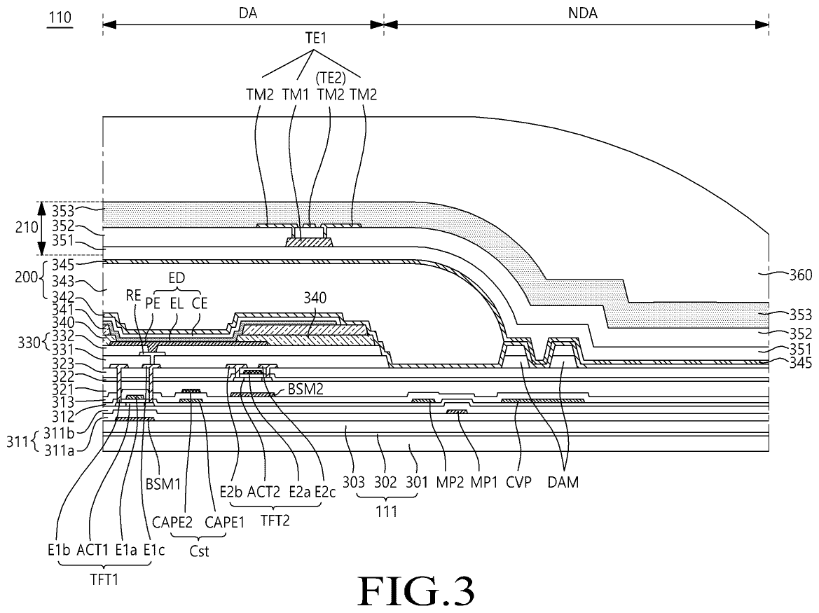

FIG. 3 is a cross-sectional view of a display panel 110 according to embodiments of the disclosure.

Referring to FIG. 3, the display panel 110 according to embodiments of the disclosure may include a transistor unit, a light emitting element unit, and an encapsulation unit, but embodiments of the disclosure are not limited thereto.

The substrate 111 may be a single layer or multiple layers. When the substrate 111 includes multiple layers, the substrate 111 may include a first substrate 301, an intermediate layer 302, and a second substrate 303. The intermediate layer 302 may be positioned between the first substrate 301 and the second substrate 303. For example, each of the first substrate 301 and the second substrate 303 may be a polyimide (PI) layer, an acrylic layer, an epoxy resin, a siloxane resin layer, a polyimide resin layer, a polymethylmetacrylicate (PMMA) layer, a polycarbonate (PC) layer, a polyvinylalcohol (PVA) layer, an acryliconitirle-butadiene-styrene (ABS) layer, a polyethylene terephthalate (PET) layer, a silicone layer, or a polyurethane (PU) layer but embodiments of the disclosure are not limited thereto. The intermediate layer 302 may be an inorganic insulation layer, but embodiments of the disclosure are not limited thereto. When an electric charge is charged to the first substrate PII which is a polyimide layer, the intermediate layer 302 may prevent the electric charge from affecting transistors disposed on the second substrate 303 through the second substrate 303 which is a polyimide layer.

Further, the intermediate layer 302 may prevent a moisture component from penetrating upward through the first substrate 301. For example, the intermediate layer 302 may be formed of a single layer of silicon nitride (SiNx), silicon oxide (SiOx), silicon oxynitride (SiOxNy) or multiple layers thereof, or may be formed of a double layer of silicon dioxide (SiO₂) and silicon nitride (SiNx), but is not limited thereto.

The transistor unit may include a substrate 111, an insulation layer 311, 312, 313, 321, 322, and 323 on the substrate 111, thin film transistors TFT1 and TFT2, a storage capacitor Cst, and various electrodes or signal lines.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The first active layer ACT1 may be a first semiconductor material, but embodiments of the disclosure are not limited thereto. For example, the first semiconductor material may include an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 may include a second semiconductor material, but embodiments of the disclosure are not limited thereto. For example, the second semiconductor material may include an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

For example, one of the first active layer ACT1 of the first thin film transistor TFT1 and the second active layer ACT2 of the second thin film transistor TFT2 may include an oxide semiconductor material. As another example, one of the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, of the first thin film transistor TFT1 and the second thin film transistor TFT2, the driving transistor DT may configure an oxide semiconductor as an active layer, and the scan transistor ST may configure low-temperature polysilicon as an active layer. As another example, of the first thin film transistor TFT1 and the second thin film transistor TFT2, the driving transistor DT may configure low-temperature polysilicon as an active layer, and the scan transistor ST may configure an oxide semiconductor as an active layer. As another example, a transistor included in a gate driving circuit 130 of a gate in panel (GIP) type may configure an oxide semiconductor or low-temperature polysilicon as an active layer. As another example, all the transistors configured on the substrate 111 and transistors included in a gate driving circuit 130 of a gate in panel (GIP) type may configure an oxide semiconductor as an active layer.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The capacitor electrodes of storage capacitor Cst may be disposed in various metal layers in the display panel 110. For example, the storage capacitor Cst may include a first capacitor electrode CAPE1 and a second capacitor electrode CAPE2.

The light emitting element portion may include a plurality of light emitting elements ED disposed on the planarization layer 330. Each of the plurality of light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers, but embodiments of the disclosure are not limited thereto. The encapsulation portion may further include a dam DAM in addition to the encapsulation layer 200.

Hereinafter, a structure, in particular a vertical structure, of the display panel 110 according to embodiments of the disclosure is described in more detail with reference to FIG. 3.

Referring to FIG. 3, the first buffer layer 311 may be disposed on the substrate 111. The first buffer layer 311 may be a single layer or multiple layers, but embodiments of the disclosure are not limited thereto. When the first buffer layer 311 includes multiple layers, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first inter-layer insulation layer 313 may be disposed on the first gate electrode E1a of the first thin film transistor TFT1. The first inter-layer insulation layer 313 may act as a dielectric layer of the storage capacitor Cst.

The second buffer layer 321 may be disposed on the first inter-layer insulation layer 313.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed on the second gate insulation layer 322. The second inter-layer insulation layer 323 may be disposed on the second gate electrode E2a of the second thin film transistor TFT2.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first metal and may be disposed in the first metal layer. Here, the first metal and the first metal layer may be referred to as a first source-drain metal and a first source-drain metal layer.

Referring to FIG. 3, e.g., the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal and formed in the same process as the first gate electrode E1a of the first thin film transistor TFT1 on the first gate insulation layer 312 to reduce the number of steps in manufacturing the display device and may be disposed in the first gate metal layer, but embodiments of the disclosure are not limited thereto. For example, the second capacitor electrode CAPE2 may be disposed on the first inter-layer insulation layer 313.

For example, when the subpixel SP is configured as shown in FIG. 2, the first thin film transistor TFT1 may be the driving transistor DT of FIG. 2, and the second thin film transistor TFT2 may be the scan transistor ST of FIG. 2.

The transistor unit may further include metal layers MP1 and MP2. For example, the first metal layer MP1 may be disposed between the lower buffer layer 311a and the upper buffer layer 311b included in the first buffer layer 311, but embodiments of the disclosure are not limited thereto. The second metal layer MP2 may include the same first gate metal as the first gate electrode E1a of the first thin film transistor TFT1, and may be disposed in the first gate metal layer, but embodiments of the disclosure are not limited thereto. The first metal layer MP1 may be a first metal pattern, and the second metal layer MP2 may be a second metal pattern, but embodiments of the disclosure are not limited thereto.

Although in FIG. 3, both the first metal layer MP1 and the second metal layer MP2 are shown as disposed in the non-display area NDA, each of the first metal layer MP1 and the second metal layer MP2 may be disposed in the display area DA or the non-display area NDA.

Referring to FIG. 3, the transistor unit may further include a first shield metal BSM1 disposed on the substrate 111. The first shield metal BSM1 may overlap the first active layer ACT1 of the first thin film transistor TFT1. The first shield metal BSM1 may be disposed under the first active layer ACT1 of the first thin film transistor TFT1. For example, as shown in FIG. 3, the first shield metal BSM1 may be disposed between the substrate 111 and the first buffer layer 311, but the present disclosure is not limited thereto, and the first shield metal BSM1 may alternatively be disposed between the lower buffer layer 311a and the upper buffer layer 311b as the first metal layer MP1 and formed in the same process as the first metal layer MP1 to reduce the number of steps in manufacturing the display device.

The transistor unit may further include a second shield metal BSM2 disposed on the substrate 111. The second shield metal BSM2 may overlap the second active layer ACT2 of the second thin film transistor TFT2. The second shield metal BSM2 may be disposed under the second active layer ACT2 of the second thin film transistor TFT2. For example, the second shield metal BSM2 may be disposed in a metal layer between the first insulation layer 313 and the second buffer layer 321. The second shield metal BSM2 may be disposed in the same metal layer as the second capacitor CAPE2, but embodiments of the disclosure are not limited thereto. As another example, the second shield metal BSM2 may be disposed in the same first gate metal layer as the first gate electrode E1a of the first thin film transistor TFT1 and the first capacitor electrode CAPE1 and may be formed in the same process as the first gate electrode E1a and the first capacitor electrode CAPE1 to reduce the number of steps in manufacturing the display device.

Referring to FIG. 3, the transistor unit may further include a common driving voltage layer CVP to which a common driving voltage is applied. For example, the common driving voltage applied to the common driving voltage layer CVP may also be referred to as a power signal, and may be a driving voltage VDD or a base voltage VSS. The driving voltage VDD may be referred to as a high-potential power supply voltage (a high-potential power supply signal or a high-potential voltage), and the base voltage VSS may be referred to as a low-potential power supply voltage (a low-potential power supply signal or a low-potential voltage).

Although in FIG. 3, the common driving voltage layer CVP is shown as disposed in the non-display area NDA, the common driving voltage layer CVP may alternatively be disposed in the display area DA.

The planarization layer 330 may be disposed on the first thin film transistor TFT1 and the second thin film transistor TFT2, and may be disposed under the light emitting element ED. The planarization layer 330 may be an organic insulation layer including an organic insulating material such as acrylic resin, phenolic resin, polyimide resin, unsaturated polyester resin, polyamide resin, benzocyclobutene, polyphenylene resin, and polyphenylene sulfide resin, etc.

For example, the planarization layer 330 may be constituted of one layer. As another example, the planarization layer 330 may include two layers. In this case, the planarization layer 330 may include a first planarization layer 331 and a second planarization layer 332, as shown in FIG. 3. As another example, the planarization layer 330 may include three or more layers. Embodiments of the disclosure are not limited thereto. The first planarization layer 331 and the second planarization layer 332 may include the same or different materials.

Referring to FIG. 3, the first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

Referring to FIG. 3, a connection electrode RE may be disposed on the first planarization layer 331. The connection electrode RE may electrically connect the first drain electrode E1c of the first thin film transistor TFT1 and the pixel electrode PE. Alternatively, the connection electrode RE may electrically connect the first source electrode E1b of the first thin film transistor TFT1 and the pixel electrode PE.

The connection electrode RE may be electrically connected to the first drain electrode E1c of the first thin film transistor TFT1 through the hole of the first planarization layer 331. Alternatively, the connection electrode RE may electrically connect the first source electrode E1b of the first thin film transistor TFT1 through the hole of the first planarization layer 331.

The connection electrode RE may be disposed in the second metal layer on the first planarization layer 331 and may include a second metal. The second metal and the second metal layer may be referred to as a second source-drain metal and a second source-drain metal layer.

The second planarization layer 332 may be disposed on the connection electrode RE.

Referring to FIG. 3, the light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The bank 340 may also be disposed on the second planarization layer 332. The opening of the bank 340 may expose a portion of the pixel electrode PE to form the emission area. The opening of the bank 340 may overlap a portion of the pixel electrode PE.

For example, the bank 340 may be formed of a material including a black pigment, a black dye such as carbon black, Kochen black, nigrosine or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

The spacer 341 may be disposed on the bank 340. When a process using a fine metal mask is performed, the spacer 341 may prevent the fine metal mask from colliding with the bank 340. Referring to FIG. 3, the spacer 341 may be disposed in a flat shape on the bank 340. However, the spacer 341 may have a semi-circular shape convex upward. Alternatively, the spacer 341 may have a conical shape, an inverted-wedged shape, a trapezoid shape that is narrow at the top and wide at the bottom, a half-oval shape, a half elliptic shape, etc. and a thickness of the spacer 341 may be larger than a thickness of the bank 340.

The spacer 341 may be an organic insulation layer including an organic insulating material. The spacer 341 may include the same material as the material included in the bank 340. For example, the spacer 341 may include an organic material such as benzocyclobutene resin, polyimide resin, acrylic resin, or photosensitive polymer. Further, the spacer 341 may be formed of a material including a black pigment or a black dye. In this case, the spacer 341 may block light from the outside or block light reflected from the outside.

The intermediate layer EL of the light emitting element ED may be disposed on a portion of the pixel electrode PE, the bank 340, and the spacer 341. The common electrode CE may be disposed on the intermediate layer EL.

The dam DAM may be disposed in the non-display area NDA adjacent to the display area DA. The second encapsulation layer 343 including the organic material may be designed to be disposed in a specific area. In this case, since the second encapsulation layer 343 includes an organic material, the second encapsulation layer 343 may flow beyond the specific area, and the dam DAM may prevent the second encapsulation layer 343 including the organic material from flowing beyond the specific area.

The number of dams DAM may be one or more. Referring to FIG. 3, e.g., the number of dams DAM may be two.

The dam DAM may include an organic material. The dam DAM may have the material as at least one of the first planarization layer 331, the second planarization layer 332, the bank 340, and the spacer 341.

For example, the dam DAM may include the same material as the material included in the first planarization layer 331. The dam DAM may include the same material as the material included in the second planarization layer 332. The dam DAM may include the same material as the material included in the bank 340. The dam DAM may include the same material as the material included in the spacer 341.

Referring to FIG. 3, the encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first encapsulation layer 342, a second encapsulation layer 343, and a third encapsulation layer 345, but embodiments of the disclosure are not limited thereto. For example, the first encapsulation layer 342 and the third encapsulation layer 345 may include an inorganic layer, and the second encapsulation layer 343 may include an organic layer, but embodiments of the disclosure are not limited thereto.

The first encapsulation layer 342 and the third encapsulation layer 345 may be disposed on the dam DAM. The first encapsulation layer 342 and the third encapsulation layer 345 may be disposed to overlap each other on the dam DAM.

The display panel 110 according to embodiments of the disclosure may include a touch sensor. In this case, the display panel 110 according to embodiments of the disclosure may include a touch sensor layer 210 formed on the encapsulation layer 200. The touch sensor layer 210 may include a touch unit.

Referring to FIG. 3, the touch sensor layer 210 may include a plurality of touch electrodes TE corresponding to touch sensors, and may include a touch metal layer on which a plurality of touch metals are disposed to form a plurality of touch electrodes TE.

For example, the touch metal layer may include a first touch metal layer on which a plurality of first touch metals TM1 are disposed, and a second touch metal layer on which a plurality of second touch metals TM2 are disposed. In this case, the touch sensor layer 210 may include a touch insulation layer 352 between the first touch metal layer and the second touch metal layer.

One of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. In other words, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may include at least one touch insulation layer.

For example, the touch sensor layer 210 may include a touch insulation layer 352 disposed between the first touch metal layer on which the plurality of first touch metals TM1 are disposed and the second touch metal layer on which the plurality of second touch metals TM2 are disposed. For example, the touch insulation layer 352 may be an inorganic layer including an inorganic insulating material or an organic layer including an organic insulating material.

As another example, the touch sensor layer 210 may further include a touch buffer layer 351 between the encapsulation layer 200 and the touch metal layer. The touch buffer layer 351 may be disposed between the encapsulation layer 200 and the first touch metal layer on which a plurality of first touch metals TM1 are disposed. Here, the touch buffer layer 351 may be omitted. For example, the touch buffer layer 351 may be an inorganic layer including an inorganic insulating material or an organic layer including an organic insulating material.

As another example, the touch sensor layer 210 may further include a first protective layer 353 on the touch metal layer. The first protective layer 353 may be disposed on the second touch metal layer on which a plurality of second touch metals TM2 are disposed. For example, the first protective layer 353 may be an inorganic layer including an inorganic insulating material or an organic layer including an organic insulating material.

Each of the plurality of touch electrodes TE may be formed of at least one second touch metal TM2. Each of the plurality of touch electrodes TE may be a mesh type electrode having a plurality of openings, but embodiments of the disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through the first touch metals TM1, which are bridge metals. For example, the second touch metals TM2 spaced apart from each other may be electrically connected by the first touch metal TM1 to constitute one first touch electrode TE1.

The plurality of first touch metals TM1 may be disposed on the touch buffer layer 351. The touch insulation layer 352 may be disposed on the plurality of first touch metals TM1. The plurality of second touch metals TM2 may be disposed on the touch insulation layer 352. Some of the plurality of second touch metals TM2 may be connected to the corresponding first touch metal TM1 through a hole in the touch insulation layer 352.

Referring to FIG. 3, the plurality of first touch metals TM1 and the plurality of second touch metals TM2 may be disposed not to overlap the light emitting element ED to prevent reduction of aperture ratio. The plurality of first touch metals TM1 and the plurality of second touch metals TM2 may overlap the bank 340.

The first protective layer 353 may be disposed on the touch metal layer. The first protective layer 353 may be disposed while covering the plurality of touch metals TM1 and TM2 disposed in the touch metal layer.

Referring to FIG. 3, a fourth encapsulation layer 360 may be disposed on the first protective layer 353. The fourth encapsulation layer 360 may be an organic encapsulation layer. The fourth encapsulation layer 360 may be disposed in the display area DA and the non-display area NDA.

Referring to FIG. 3, a portion of the upper surface of the fourth encapsulation layer 360 may be disposed to be flat in the display area DA. A portion of the upper surface of the fourth encapsulation layer 360 may be disposed to be inclined in the non-display area NDA. For example, referring to FIG. 3, the upper surface of the fourth encapsulation layer 360 may be disposed to be flat in the non-display area NDA adjacent to the display area DA and then inclined to the lower right.

Hereinafter, the display area DA and the non-display area NDA are described.

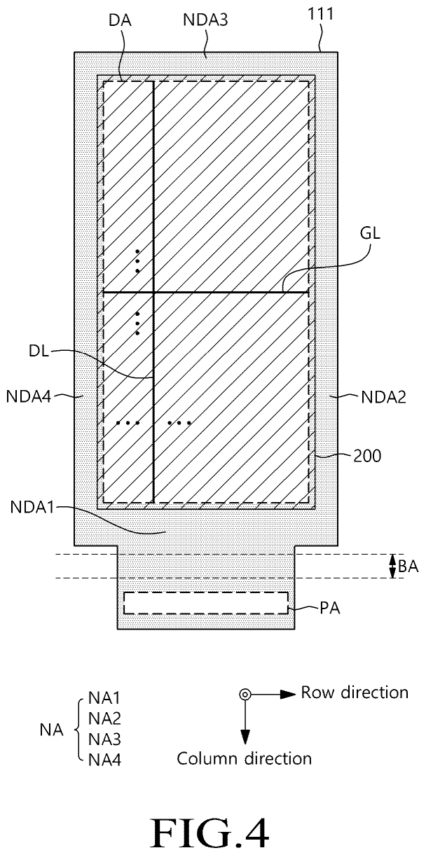

FIG. 4 illustrates a substrate 111 of a display panel 110 according to embodiments of the disclosure.

Referring to FIG. 4, the substrate 111 of the display panel 110 according to embodiments of the disclosure may include a display area DA in which an image may be displayed and a non-display area NDA in which an image is not displayed.

The non-display area NDA may include a first non-display area NDA1, a second non-display area NDA2, a third non-display area NDA3, and a fourth non-display area NDA4.

The first non-display area NDA1 may be positioned in the column direction from the display area DA. The second non-display area NDA2 may be positioned in the row direction from the display area DA. The third non-display area NDA3 may be positioned in the column direction from the display area DA and opposite to the first non-display area NDA1. The fourth non-display area NDA4 may be positioned in the row direction from the display area DA and opposite to the second non-display area NDA2.

For example, the column direction may be a direction in which data lines DL are disposed to extend, and the row direction may be a direction in which gate lines GL are disposed to extend. As another example, the column direction may be a direction in which gate lines GL are disposed to extend, and the row direction may be a direction in which data lines DL are disposed to extend. The column direction and the row direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto.

Referring to FIG. 4, the first non-display area NDA1 may include a pad area PA in which a plurality of pads to which at least one driving circuit or printed circuit board is electrically connected are disposed. For example, a plurality of data lines DL, a driving voltage line (not illustrated) and a base voltage line (not illustrated) may be electrically connected to the plurality of pads.

The display panel 110 may further include a ground line (not illustrated) disposed in the non-display area NDA of the substrate 111. The ground line may be disposed from one point of the pad area PA to another point of the pad area PA via the second non-display area NDA2, the third non-display area NDA3, and the fourth non-display area NDA4.

In the display panel 110 according to embodiments of the disclosure, the encapsulation layer 200 may have a structure in which an inorganic film and an organic film are stacked, but embodiments of the disclosure are not limited thereto. In this case, an edge of the encapsulation layer 200 may be an edge of the organic film. The encapsulation layer 200 may extend or expand from the display area DA to a portion of the non-display area NDA, but embodiments of the disclosure are not limited thereto.

The display panel 110 according to embodiments of the disclosure may include at least one dam DAM or at least one stopper positioned farther outside than the organic film included in the encapsulation layer 200 to prevent overflow of the organic film included in the encapsulation layer 200. The at least one dam or the at least one stopper may include an organic film, but embodiments of the disclosure are not limited thereto.

The first non-display area NDA1 may further include a bending area BA. In this case, the substrate 111 may be a flexible substrate. In some cases, the first non-display area NDA1 may not include the bending area BA.

The bending area BA of the display panel 110 may be bent. Hereinafter, a state in which the bending area BA of the display panel 110 is bent is described.

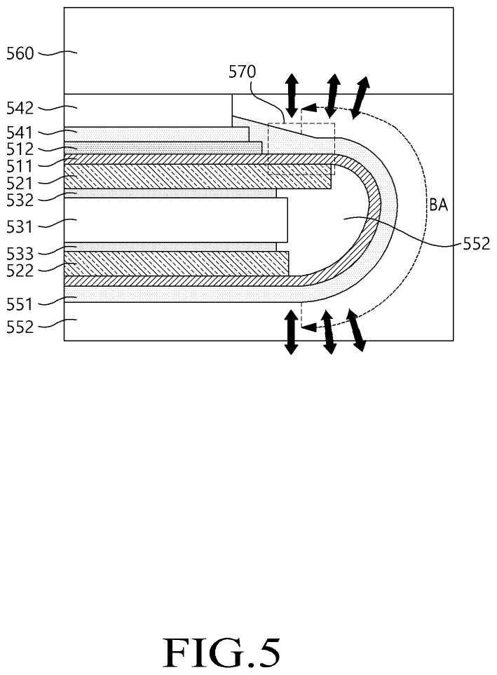

FIG. 5 is a cross-sectional view illustrating a bending area BA of a display device according to embodiments of the disclosure.

The display panel 110 may include a bendable portion and a non-bending portion.

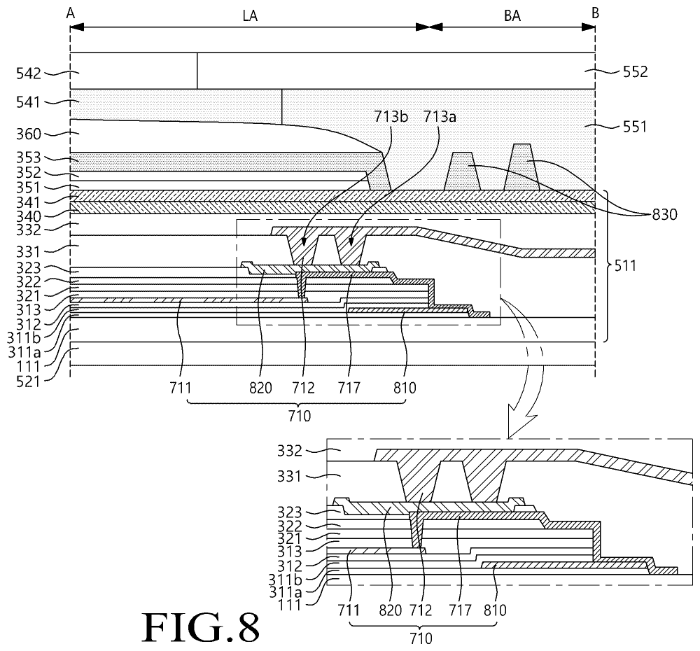

The flexible substrate 511 of the display panel 110 may be a portion of the bendable display panel 110. The flexible substrate 511 of the display panel 110 may include the components of the bending area BA illustrated in FIG. 8. For example, the flexible substrate 511 of the display panel 110 may include at least a substrate 111, a first planarization layer 331, a metal line 712, a second planarization layer 332, and a dam 830. Referring to FIG. 5, the flexible substrate 511 of the display panel 110 may be bent in the bending area BA. The flexible substrate 511 of the display panel 110 may be maintained in a flat state without being bent in the area 570 adjacent to the bending area BA.

The image display portion 511 of the display panel 110 may be a portion of the display panel 110 that is not bent. For example, the image display portion 511 of the display panel 110 may include the components of the link area LA illustrated in FIG. 8. For example, the image display portion 511 of the display panel 110 may include the first protective layer 353 and the second organic layer 360 illustrated in FIG. 8.

The polarizing layer 542 and the adhesive layer 541 may be disposed on the image display portion 511 of the display panel 110.

A first support substrate 521 and a second support substrate 522 may be disposed under the flexible substrate 511 of the display panel 110.

The flexible substrate 511 of the display panel 110 may be bent in the bending area BA. After the flexible substrate 511 of the display panel 110 corresponding to the bending area BA is bent, the first support substrate 521 and the second support substrate 522 may be fixed to the fixing portion 531.

The first support substrate 521 may be fixed to the fixing portion 531 through a first adhesive layer 532.

The second support substrate 522 may be fixed to the fixing portion 531 through a second adhesive layer 533.

The first adhesive layer 532 and the second adhesive layer 533 may be a film-type transparent adhesive. For example, the fixing portion 531 may be a pressure-sensitive adhesive, an optically cleared adhesive, an optically cleared resin etc.

After the flexible substrate 511 of the display panel 110 is bent, a second protective layer 551 may be disposed in the bending area BA of the flexible substrate 511 of the display panel 110. The second protective layer 551 may prevent moisture from penetrating into the bending area BA or prevent cracks from occurring in the bending area BA.

The second protective layer 551 may be disposed outside the polarizing layer 542, and the second protective layer 551 may be disposed in contact with the polarizing layer 542.

The cured layer 552 may be disposed outside the second protective layer 551. For example, the cured layer 552 may be a thermosetting adhesive, a photo curable adhesive such as UV curable adhesive. The cured layer 552 may be disposed outside the polarizing layer 542, and the cured layer 552 may be disposed in contact with the polarizing layer 542. The cure layer 552 may be located not only on the outer side of the second protective layer 551 but also on the inner side of the second protective layer 551. Referring to FIG. 5, the cure layer 552 may be located on the inner side between the second protective layer 551 and the fixing portion 531, and the cure layer 552 may be placed on the outer side rather than the inner side. the cured layer 552 may also be disposed in the area surrounded by the inner side of the first support substrate 521, the flexible substate 511, the first adhesive layer 532, the fixing portion 531, the second adhesive layer 533, and the second support substrate 522.

A cover glass 560 may be disposed on the polarizing layer 542 and the cured layer 552. The cover glass 560 may protect the display panel 110 from an external impact.

The cured layer 552 may contract or expand according to changes in the external environment. For example, the cured layer 552 may contract or expand according to a temperature change. The cured layer 552 may be contracted or expanded by an external impact.

In particular, when the cured layer 552 is contracted or expanded, the impact may be concentrated on the end portion 570 of the bending area BA. In this case, a crack may occur in the end portion 570 of the bending area BA.

According to embodiments of the disclosure, cracks generated in the end portion 570 of the bending area BA may be prevented through the first metal pattern 717 disposed in the link area LA and the bending area BA. Further, cracks occurring in the end portion 570 of the bending area BA may be prevented through the second metal pattern 810 disposed to overlap the first metal pattern 717 in the link area LA.

In other words, embodiments of the disclosure may provide a display device 100 capable of preventing cracks in the non-display area NDA.

Embodiments of the disclosure may provide a display device 100 capable of strengthening the bending area BA adjacent to the link area LA.

Embodiments of the disclosure may provide a display device 100 capable of optimizing a process by preventing cracks that may occur during a process.

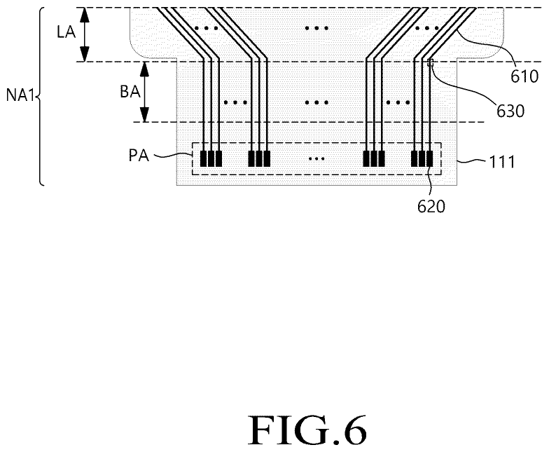

FIG. 6 is a plan view illustrating a first non-display area NDA1 according to embodiments of the disclosure.

Referring to FIG. 6, the first non-display area NDA1 may include a link area LA, a bending area BA, and a pad area PA.

Referring to FIG. 6, a plurality of signal lines 610 may be disposed in the first non-display area NDA1.

Referring to FIG. 6, a plurality of pads 620 may be disposed in the pad area PA, and the data driving circuit 120 may be electrically connected thereto.

The plurality of signal lines 610 may be electrically connected to the plurality of pads 620.

Each of the plurality of signal lines 610 may be disposed in a linear shape in the pad area PA and the bending area BA. Each of the plurality of signal lines 610 may be disposed in a row.

The plurality of signal lines 610 may be disposed in a linear shape in the link area LA adjacent to the bending area BA. The plurality of signal lines 610 disposed in the link area LA may be disposed in a diagonal shape spreading to the left and right as the distance from the bending area BA increases.

The plurality of signal lines 610 may be lines to which a voltage or signal is supplied. For example, the plurality of signal lines 610 may include a line to which a data voltage is supplied, a line to which a gate signal is supplied, a line to detect a characteristic value of a subpixel, a line to which a touch driving signal is supplied, a line to sense the presence or absence of a touch, and a line to supply a voltage other than a data voltage (such as a power voltage), but the present disclosure is not limited thereto.

The plurality of signal lines 610 may be formed of one line or two or more lines, but embodiments of the disclosure are not limited thereto. The plurality of signal lines 610 may be disposed in one metal layer or two or more metal layers, but embodiments of the disclosure are not limited thereto.

The bending area BA may be bent during manufacturing of the display panel 110. Accordingly, when the user views the display device 100 from the front, the bending area BA and the pad area PA are not visible from the front.

Meanwhile, when the bending area BA is bent, cracks may occur in the bending area BA adjacent to the link area LA.

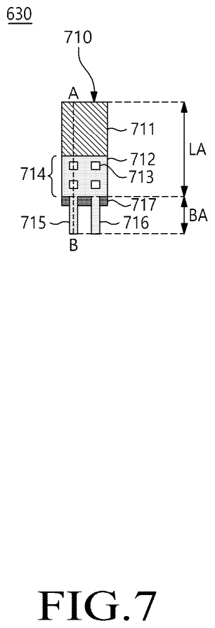

Referring to FIG. 7, an enlarged plan view of a partial area 630 of FIG. 6 may be identified.

FIG. 7 is an enlarged view illustrating a partial area 630 of the plan view of the display panel 110 of FIG. 6. FIGS. 8, 9, and 10 are cross-sectional views of area A-B of FIG. 7.

Each of the plurality of signal lines 610 may include metals disposed in different layers. Hereinafter, one signal line 710 included in a plurality of signal lines 610 is described as an example.

Referring to FIGS. 7 and 8, the signal line 710 may include a first metal 711, a metal line 712, a contact hole 713, and a first metal pattern 717.

The signal line 710 may be disposed in the link area LA and the bending area BA.

The signal line 710 may include the first metal 711 and the metal line 712.

The first metal 711 may be disposed in the link area LA. The metal line 712 may be disposed in the bending area BA and the link area LA adjacent to the bending area BA.

Referring to FIG. 8, the first metal 711 may be disposed to overlap the metal line 712 in the link area LA.

The first metal 711 may contact the metal line 712 through one or more contact holes 713. For example, referring to FIG. 7, there may be four contact holes 713. As the number of contact holes 713 increases, contact resistance that may occur in the contact hole 713 may be relatively decreased.

The metal line 712 may be disposed to extend from the link area LA to the bending area BA. A portion of the metal line 712 extending to the bending area BA may include one or more metal portions.

For example, the metal line 712 may include a first line 714, a second line 715, and a third line 716.

The first line 714 may be disposed in the link area LA.

The second line 715 may extend from the first line 714 and may be disposed in the bending area BA.

The third line 716 may extend from the first line 714 and may be disposed in the bending area BA.

The line width of the first line 714 may be larger than each of the line width of the second line 715 and the line width of the third line 716.

The second line 715 may be disposed to be spaced apart from the third line 716.

At least a portion of the first line 714 may vertically overlap the first metal pattern 717, and at least a portion of the second line 715 and the third line 716 may overlap the first metal pattern 717.

At least a portion of the first line 714 may vertically overlap the first metal 711, and the second line 715 and the third line 716 may not overlap the first metal 711.

By decreasing the line width of the metal line 712 disposed in the bending area BA, cracks that may occur in the bending area BA may be prevented.

Meanwhile, the first metal pattern 717 may be disposed to extend from the link area LA to the bending area BA adjacent to the link area LA. Accordingly, cracks that may occur in the bending area BA may be prevented.

Referring to FIG. 7, area A-B may be identified. Hereinafter, a cross-sectional view of area A-B is described in detail with reference to FIG. 8.

The first support substrate 521 may be disposed under the substrate 111. The strength of the first support substrate 521 may be greater than the strength of the substrate 111. In one aspect, the first support substrate 521 may be stronger than the substrate 111. In one aspect, the first support substrate 521 may be stronger than the substrate 111 so that the first support substrate 521 may be less breakable than the substrate 111. As the first support substrate 521 is disposed under the substrate 111, a portion of the substrate 111 disposed to overlap the first support substrate 521 may not be bent. The substrate 111 may include a first substrate 301, an intermediate layer 302, and a second substrate 303 illustrated in FIG. 3.

The lower buffer layer 311a may be disposed on the substrate 111. The lower buffer layer 311a may be disposed in the link area LA and the bending area BA adjacent to the link area LA such that the second metal pattern 810 formed thereon extends to the bending area BA.

The second metal pattern 810 may be disposed on the lower buffer layer 311a. The second metal pattern 810 may include the same material as the material included in the first shield metal BSM1 illustrated in FIG. 3. The second metal pattern 810 may be disposed to extend from the link area LA adjacent to the bending area BA to the start portion of the bending area BA.

An end of the second metal pattern 810 may coincide with an end of the lower buffer layer 311a. However, an end of the second metal pattern 810 may not coincide with an end of the lower buffer layer 311a. For example, referring to FIG. 7, an end of the second metal pattern 810 may be disposed farther to the left than the end of the lower buffer layer 311a. Alternatively, the end of the second metal pattern 810 may be disposed up to the outside of the end of the lower buffer layer 311a.

The upper buffer layer 311b may be disposed on the lower buffer layer 311a and the second metal pattern 810. Referring to FIG. 8, the upper buffer layer 311b may be disposed to contact the upper surface of the lower buffer layer 311a. The lower buffer layer 311a may be disposed to contact the upper surface of the second metal pattern 810 disposed to overlap the lower buffer layer 311a and the upper buffer layer 311b.

An end of the upper buffer layer 311b may coincide with a boundary between the bending area BA and the link area LA, but is not limited thereto.

The first gate insulation layer 312 may be disposed on the upper buffer layer 311b. An end of the first gate insulation layer 312 may coincide with an end of the upper buffer layer 311b, but the disclosure is not limited thereto.

The first metal 711 may be disposed on the first gate insulation layer 312. The first metal 711 may include the same material as the material of the first gate electrode E1a illustrated in FIG. 3. In other words, the material included in the first gate electrode E1a may also be included in the first metal 711. The first metal 711 may be positioned on the same layer as the second metal layer MP2 and the first capacitor electrode CAPE1 shown in FIG. 3.

The first metal 711 may be disposed to expose a portion of the first gate insulation layer 312.

The first interlayer insulation layer 313 may be disposed on the first metal 711 and the first gate insulation layer 312.

Referring to FIG. 8, the position of the end of the first interlayer insulation layer 313 may coincide with the position of the end of the first gate insulation layer 312. However, the position of the end of the first interlayer insulation layer 313 may be different from the position of the end of the first gate insulation layer 312. For example, the position of the end of the first interlayer insulation layer 313 may be disposed farther to the left or farther to the right than the position of the end of the first gate insulation layer 312.

Referring to FIG. 8, the boundary between the link area LA and the bending area BA may correspond to the position of the end of the first interlayer insulation layer 313. Alternatively, the boundary between the link area LA and the bending area BA may correspond to the position of the end of the second gate insulation layer 322.

The second buffer layer 321 may be disposed on the first interlayer insulation layer 313. The end of the second buffer layer 321 may coincide with the end of the first interlayer insulation layer 313, but the disclosure is not limited thereto. For example, the position of the end of the second buffer layer 321 may be disposed farther to the left or farther to the right than the position of the end of the first interlayer insulation layer 313.

The boundary between the link area LA and the bending area BA may correspond to the position of the end of the second buffer layer 321, without limited thereto.

The second gate insulation layer 322 may be disposed on the second buffer layer 321.

Referring to FIG. 8, the position of the end of the second gate insulation layer 322 may be disposed farther to the left than the position of the end of the second buffer layer 321. In other words, the position of the end of the second gate insulation layer 322 may be different from the position of the end of the second buffer layer 321. Alternatively, the position of the end of the second gate insulation layer 322 may be the same as the position of the end of the second buffer layer 321.

The first metal pattern 717 may be disposed on the second gate insulation layer 322, and may have the same material and formed in the same process as the second gate electrode E2a shown in FIG. 3 to reduce the number of steps in manufacturing the display device.

The first metal pattern 717 may be disposed on the second gate insulation layer 322 and may extend to the bending area BA.

Referring to FIG. 8, the first interlayer insulation layer 313, the second buffer layer 321, and the second gate insulation layer 322 may each include a contact hole. The first metal pattern 717 may be disposed in contact with the first metal 711 through the contact hole of each of the first interlayer insulation layer 313, the second buffer layer 321, and the second gate insulation layer 322. In other words, the first metal pattern 717 may be electrically connected to the first metal 711. The first metal pattern 717 may include a different material from the first metal 711.

The first metal pattern 717 may be positioned at the boundary between the link area LA and the bending area BA. The first metal pattern 717 may be disposed in the link area LA adjacent to the bending area BA. The first metal pattern 717 may extend from the link area LA to the bending area BA.

The first metal pattern 717 may be disposed on a portion of the upper surface of the second gate insulation layer 322, the upper surface of a portion of the second buffer layer 321, side surfaces of the insulation layers (the upper buffer layer 311b, the first gate insulation layer 312, the first interlayer insulation layer 313, and the second upper layer 321), the upper and side surfaces of the second metal pattern 810, the side surface of the lower buffer layer 311a, and a portion of the upper surface of the substrate 111. The edge portion of the first metal pattern 717 may contact the upper surface of the substrate 111.

As the first metal pattern 717 is disposed at the boundary between the link area LA and the bending area BA, the bending area BA adjacent to the link area LA may be designed to be robust. In other words, cracks may occur in the bending area BA adjacent to the link area LA. As the first metal pattern 717 is disposed at the boundary between the link area LA and the bending area BA, cracks may be prevented.

The second interlayer insulation layer 323 may be disposed on a portion of the second gate insulation layer 322 and the first metal pattern 717.

After the entire deposition of the second interlayer insulation layer 323, a portion of the second interlayer insulation layer 323 may be etched away so as to form the connection pattern 820.

The connection pattern 820 may be disposed in contact with and overlapping the first metal pattern 717 in the area where the second interlayer insulation layer 323 is etched away.

Referring to FIG. 8, the connection pattern 820 may be disposed in contact with and overlapping a portion of the second interlayer insulation layer 323 and a portion of the first metal pattern 717.

After the connection pattern 820 is disposed, the first planarization layer 331 may be entirely deposited.

Referring to FIG. 8, the first planarization layer 331 may be disposed on the second interlayer insulation layer 323, the connection pattern 820, the first metal pattern 717, and the substrate 111. The first planarization layer 331 may extend to the bending area BA from the link area LA.

The first planarization layer 331 may be the same as the first planarization layer 331 illustrated in FIG. 3.

After the first planarization layer 331 is deposited, a contact hole may be formed in the first planarization layer 331. In other words, the first planarization layer 331 may include at least one contact hole. Referring to FIGS. 8 to 10, the first planarization layer 331 may include a first contact hole 713a and a second contact hole 713b.

The first contact hole 713a may electrically connect the metal line 712 to the first metal pattern 717. The first contact hole 713a may be positioned closer to the bending area than the second contact hole 713b.

The metal line 712 may be disposed to extend from the point where the first contact hole 713a is present to the bending area BA.

The metal line 712 may be connected to the connection pattern 820 through the first contact hole 713a, and the connection pattern 820 may be connected to the first metal pattern 717.

The second contact hole 713b may electrically connect the metal line to the first metal pattern. The second contact hole 713b may be positioned closer to the display area than the first contact hole 713a.

A metal line 712 may be disposed on the first planarization layer 331, and the metal line 712 may be disposed to contact the connection pattern 820 through the contact hole formed in the first planarization layer 331.

Referring to FIG. 8, in cross-sectional view, the metal line 712 may be disposed in contact with the connection pattern 820 through two contact holes. Referring to FIG. 7, in plan view, the metal line 712 may be disposed in contact with the connection pattern 820 through four contact holes 713. The metal line 712 may be disposed in contact with the connection pattern 820 through more than four contact holes 713.

The metal line 712 may be disposed in contact with and overlapping the connection pattern 820 in the link area LA, and may be disposed to extend to the bending area BA.

The second planarization layer 332 may be disposed on the first planarization layer 331 and the metal line 712. The second planarization layer 332 may extend to the bending area BA from the link area LA.

The first metal pattern 717 and the second metal pattern 810 may be disposed to overlap the first planarization layer 331 and the second planarization layer 332 in the link area LA adjacent to the bending area BA. For example, the first metal pattern 717 may be disposed between the first planarization layer 331 and the second planarization layer 332, but the present disclosure is not limited thereto.

The thickness of the second planarization layer 332 positioned in the bending area BA may be larger than the thickness of the second planarization layer 332 overlapping the first interlayer insulation layer 313.

The second planarization layer 331 positioned in the bending area BA may be lower in height from the substrate than the second planarization layer 331 overlapping the first interlayer insulation layer 313. For example, the lower surface of the second planarization layer 331 positioned in the bending area BA may be lower in height from the substrate than the lower surface of the second planarization layer 331 overlapping the first interlayer insulation layer 313.

The first metal pattern 717 may be positioned to overlap the first planarization layer 331 positioned in the bending area BA and the second planarization layer 332 positioned in the bending area BA.

The bank 340 may be entirely deposited on the second planarization layer 332. The spacer 341 may be entirely deposited on the bank 340. The spacer 341 and the bank 340 may have the same material and formed in the same process as the spacer 341 and the bank 340 shown in FIG. 3, respectively to reduce the number of steps in manufacturing the display device. Referring to FIG. 8, the bank 340 and the spacer 341 are disposed to extend from the link area LA to the bending area BA. However, the bank 340 and the spacer 341 may not be disposed in the link area LA and the bending area BA.

A touch buffer layer 351 may be disposed on the spacer 341. A touch insulation layer 352 may be disposed on the touch buffer layer 351. An end of the touch buffer layer 351 may coincide with an end of the touch insulation layer 352. The touch buffer layer 351 and the touch insulation layer 352 may be disposed in the link area LA, and may be disposed up to the link area LA close to the bending area BA. The touch buffer layer 351 and the touch insulation layer 352 may have the same material as the touch buffer layer 351 and the touch insulation layer 352 shown in FIG. 3, respectively to reduce the number of steps in manufacturing the display device. However, the bank 340 and the spacer 341 may not be disposed in the link area LA and the bending area BA, and in the case, the touch buffer layer 351 may be disposed on the second planarization layer 332.

The first protective layer 353 may be disposed on the touch insulation layer 352. The first protective layer 353 may have the same material as the first protective layer 353 shown in FIG. 3 to reduce the number of steps in manufacturing the display device. The first protective layer 353 may be disposed in contact with the side surfaces of the touch buffer layer 351 and the touch insulation layer 352. The first protective layer 353 may be disposed up to the boundary between the link area LA and the bending area BA. Alternatively, the first protective layer 353 may be disposed up to the bending area BA adjacent to the link area LA.

Thereafter, as a portion of the first protective layer 353 is etched, the dam 830 may be disposed. However, the dam 830 may not include the same material as the material of the first protective layer 353. In this case, the dam 830 may be disposed in the bending area BA after the first protective layer 353 is disposed. However, according to the design purpose, the dam 830 may be excluded from the display panel 110.

The number of dams 830 may be one or more. For example, referring to FIG. 8, the number of dams 830 may be two. Any one dam 830 may be disposed in the bending area BA, and the other dam 830 may be disposed at the boundary between the bending area BA and the link area LA. However, the dam 830 may also be disposed in the link area LA. The height of the dams may be the same as or different from each other. For example, in case two dams are disposed in the bending area BA as shown in FIG. 8, the right dam may have a higher height than the left dam prevent overflow of the second organic layer 360.

After the first protective layer 353 is disposed, the second organic layer 360 may be disposed. The second organic layer 360 may extend not exceeding the end of the first protective layer 353. The second organic layer 360 have the same material and formed in the same process as the second organic layer 360 shown in FIG. 3 to reduce the number of steps in manufacturing the display device. The dam 830 may prevent the second organic layer 360 from being displaced from a specific position when the second organic layer 360 is formed.

However, the dam 830 may be disposed in the link area LA, not the bending area BA. Alternatively, the dam 830 may not be disposed on the spacer 341.

The polarizing layer 542 may be disposed on the second organic layer 360. To fix the polarizing layer 542, the adhesive layer 541 may be disposed between the polarizing layer 542 and the second organic layer 360. For example, the adhesive layer 541 may be a film-type transparent adhesive such as a pressure sensitive adhesive (PSA), an optically cleared adhesive (OCA), an optically cleared resin (OCR), etc.

In order to protect the bending area BA, the second protective layer 551 may be disposed in the bending area BA and the link area LA adjacent to the bending area BA.

As the second protective layer 551 is disposed in the bending area BA, a line (e.g., 710 illustrated in FIG. 8) disposed in the bending area BA may be protected.

For example, it is possible to prevent moisture from penetrating into the line disposed in the bending area BA, or to prevent cracks from occurring in the line disposed in the bending area BA.

The cured layer 552 may be disposed outside the second protective layer 551. As the cured layer 552 is disposed outside the second protective layer 551, components inside the second protective layer 551 and the second protective layer 551 may be protected from external impact.

The cured layer 552 may include an epoxy-based resin material such as ethylene oxide, Bisphenol A Epoxy Resin, Bisphenol F Epoxy Resin, Phenolic Epoxy Resin, Cycloaliphatic Epoxy Resin, etc.

The cured layer 552 may be disposed in contact with the polarizing layer 542 and the adhesive layer 541.

The cured layer 552 may contract or expand according to a change in an external environment.

Since the cured layer 552 is disposed in the bending area BA and the link area LA adjacent to the bending area BA, when the cured layer 552 extends or contracts, cracks may occur in the bending area BA adjacent to the link area LA.

In the bending area BA, the second protective layer 551 and the cured layer 552 are bent together, and the first metal pattern 717 may be disposed to overlap the contractible or expandable cured layer 552.

Since the first metal pattern 717 is disposed in the link area LA and the bending area BA adjacent to the link area LA, cracks may be prevented from occurring in the bending area BA adjacent to the link area LA.

The first metal pattern 717 may be electrically connected to the second metal pattern 810, and may extend to at least a partial area in the bending area BA positioned farther outside than the edge of the first interlayer insulation layer 313.

Further, since the second metal pattern 810 is disposed to overlap the first metal pattern 717 in the link area LA adjacent to the bending area BA, cracks may be prevented from occurring in the bending area BA adjacent to the link area LA through the second metal pattern 810 and the first metal pattern 717.

The position where the first metal pattern 717 contacts the first metal 711 may overlap the position where the connection pattern 820 contacts the metal line 712. The first metal pattern 717 may be disposed to extend from the corresponding position to the bending area BA adjacent to the link area LA.

The position where the first metal pattern 717 contacts the connection pattern 820 may overlap the position where the connection pattern 820 contacts the metal line 712.

The first metal pattern 717 may be disposed to overlap the second metal pattern 810. The first metal pattern 717 may be disposed to be spaced apart from the second metal pattern 810 at the position in contact with the first interlayer insulation layer 313. The first metal pattern 717 may be disposed to extend along the side surfaces of the second gate insulation layer 322, the second buffer layer 321, the first interlayer insulation layer 313, the first gate insulation layer 312 and the upper buffer layer 311b, and the extended first metal pattern 717 may be disposed in contact with the second metal pattern 810 and then may be disposed to extend to the bending area BA.

The first metal pattern 717 may be disposed to extend to the bending area BA while contacting the side surface portion of the second metal pattern 810. The first metal pattern 717 may be disposed in contact with the side surface portion of the second metal pattern 810 and the side surface portion of the lower buffer layer 311a.

The second metal pattern 810 may be disposed to extend from the bending area BA or the boundary between the bending area BA and the link area LA toward the link area LA. The second metal pattern 810 may be disposed to extend to the position where the connection pattern 820 contacts the metal line 712. The position where the connection pattern 820, the metal line 712, and the first metal pattern 717 overlap may overlap the position where the second metal pattern 810 is disposed.

Referring to FIG. 8, in cross-sectional view, an end of the second metal pattern 810 is disposed up to the bending area BA, but an end of the second metal pattern 810 may be disposed up to the boundary between the bending area BA and the link area LA.

Referring to FIGS. 7 and 8, the signal line 710 illustrated in FIG. 7 may include the first metal 711, the first metal pattern 717, the connection pattern 820, the metal line 712 and the second metal pattern 810 illustrated in FIG. 8.

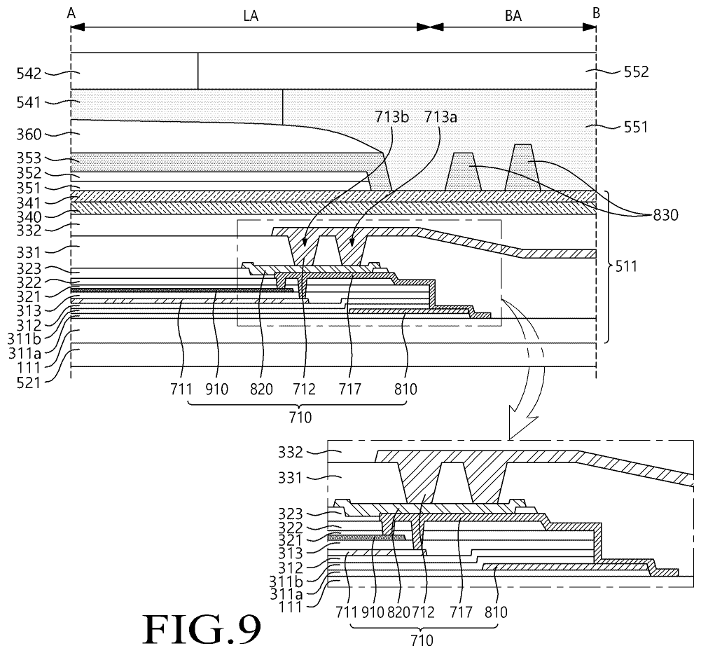

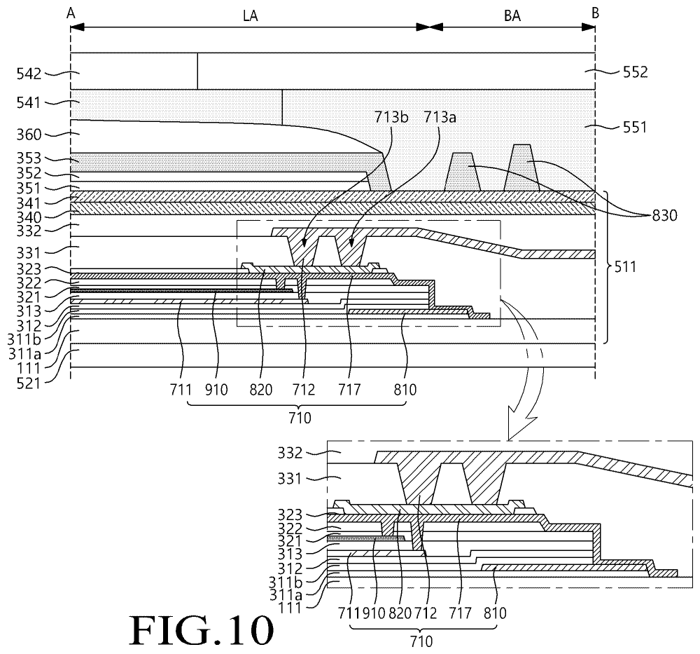

A single line structure is illustrated in FIG. 8, a double line structure is illustrated in FIG. 9, and a triple line structure is illustrated in FIG. 10. The single line, double line, and triple line mean a multi-line, and the definition of the multi-line is as follows. The criterion of “multi” in the multi-line refers to the number of metal layers where the first metal pattern 717 and/or at least one connection metal (e.g., first metal 711 or second metal 910) is disposed inside the point where the first metal pattern 717 is connected to at least one other connection metal.

For example, the signal line 710 may electrically connect the pad 620 of the pad area PA and the gate driving circuit (not illustrated) of the non-display area NDA. When the first metal pattern 717 is electrically connected to the gate driving circuit (not illustrated) by the first metal 711, it may be referred to as a single line structure. In addition to the first metal 711, when the first metal pattern 717 is electrically connected to the gate driving circuit (not illustrated) by the second metal 910, it may be referred to as a double line structure. In addition to the first metal 711 and the second metal 910, when the first metal pattern 717 is also connected in direct contact with the gate driving circuit (not illustrated), it may be referred to as a triple line structure.

When the signal line 710 corresponding to the portion extending from the link area LA to the display area AA includes lines other than the first metal 711, it may be a double line structure or a triple line structure. A double line structure is illustrated in FIG. 9, and a triple line structure is illustrated in FIG. 10.

Referring to FIG. 9, the second metal 910 may be disposed between the first interlayer insulation layer 313 and the second gate insulation layer 322. For example, the second metal 910 may be disposed in the second buffer layer 321 between the first interlayer insulation layer 313 and the second gate insulation layer 322. The second metal 910 may be a touch metal that is a portion of a touch routing line.

The second metal 910 may be disposed in contact with the first metal pattern 717 through the contact hole formed in the second gate insulation layer 322 and the second buffer layer 321.

The signal line 710 corresponding to the portion extending from the link area LA to the display area AA may include a first metal 711 and a second metal 910. Since the first metal 711 and the second metal 910 are disposed in parallel, the resistance component of the signal line 710 may be decreased.

The first metal pattern 717 may be disposed to extend from the position overlapping the second metal 910 to the bending area.

The first metal pattern 717 may be disposed on the second buffer layer 321 or the second gate insulation layer 322. At least a portion of the first metal pattern 717 may overlap the second metal 910. The first metal pattern 717 may include a first connection portion connected to the second metal 910 through the contact hole of the second buffer layer 321 and the second gate insulation layer 322, and a second connection portion connected to the first metal through the contact hole of the first interlayer insulation layer 313, the second gate insulation layer 322 and the second buffer layer 321.

Referring to FIG. 10, the second metal 910 may be disposed between the first interlayer insulation layer 313 and the second gate insulation layer 322. For example, the second metal 910 may be disposed in the second buffer layer 321 between the first interlayer insulation layer 313 and the second gate insulation layer 322. The second metal 910 may be a touch metal that is a portion of a touch routing line.

The first metal pattern 717 may be disposed between the second gate insulation layer 322 and the second interlayer insulation layer 323, and may be disposed to extend from the link area LA to the display area AA. The first metal pattern 717 may be disposed to extend from the link area LA to the display area AA while contacting the second gate insulation layer 322.

The first metal pattern 717 may be disposed to extend in a direction away from the bending area BA while overlapping the first metal 711 and the second metal 910.

The first metal pattern 717 may include a first connection portion connected to the second metal 910 through the contact hole of the second buffer layer 321 and the second gate insulation layer 322, and a second connection portion connected to the first metal through the contact hole of the first interlayer insulation layer 313, the second gate insulation layer 322 and the second buffer layer 321. The first metal pattern 717 may further include an extension extending from the first connection portion toward the display area DA.

The signal line 710 corresponding to the portion extending from the link area LA to the display area AA may include a first metal 711, a second metal 910, and a first metal pattern 717. Since the first metal 711, the second metal 910, and the first metal pattern 717 are disposed in parallel, the resistance component of the signal line 710 may be decreased.

Embodiments of the disclosure described above are briefly described below.

Embodiments of the disclosure may provide a display device comprising a substrate, a display area, a non-display area positioned outside the display area and including a bending area, a first metal disposed on the substrate and positioned in the display area or positioned closer to the display area than the bending area in the non-display area, a first insulation layer disposed on the first metal and extending farther outside than the first metal, and a first metal pattern disposed on the first insulation layer, electrically connected to the first metal, and extending through an edge side surface of the first insulation layer to at least a partial area in the bending area.

The display device may further comprise a second metal disposed on the first insulation layer and electrically connected to the first metal pattern, and an interlayer insulation layer on the second metal. The first metal pattern may be disposed on the interlayer insulation layer. At least a portion of the first metal pattern may overlap the second metal. The first metal pattern may include a first connection portion connected to the second metal through a contact hole of the interlayer insulation layer, and a second connection portion connected to the first metal through a contact hole of the first insulation layer and the interlayer insulation layer.

The first metal pattern may further include an extension extending from the first connection portion toward the display area.

The display device may further comprise a first transistor disposed in the display area on the substrate, and including a first active layer, a first gate electrode, a first source electrode, and a first drain electrode. The first metal may include the same material as a material of the first gate electrode of the first transistor. The first metal pattern may include a material different from the first metal.

The display device may further comprise a second transistor disposed in the display area on the substrate, and including a second active layer, a second gate electrode, a second source electrode, and a second drain electrode. The first metal pattern may include the same material as a material of the second gate electrode of the second transistor.

The second active layer may be farther away from the substrate than the first active layer. The first active layer and the second active layer may include different semiconductor materials.

The display device may further comprise second insulation layer disposed on the first metal pattern, and a metal line on the second insulation layer. The second insulation layer may include a first contact hole for electrically connecting the metal line and the first metal pattern. The metal line may extend from a point where there first contact hole may be present to the bending area. The first contact hole may be positioned between the display area and the bending area.

The display device may further comprise a connection pattern disposed between the first metal pattern and the second insulation layer. The metal line may be connected to the connection pattern through the first contact hole, and the connection pattern may be connected to the first metal pattern.

The connection pattern may include the same material as a material of a source or drain electrode of a transistor disposed in the display area. The first metal pattern may include the same material as a gate electrode of the transistor.

The second insulation layer may further include a second contact hole for electrically connecting the metal line and the first metal pattern. The second contact hole may be positioned closer to the display area than the first contact hole.

The metal line may include a first line disposed in a link area between the display area and the bending area, a second line extending from a portion of the first line and disposed in the bending area, and a third line extending from a portion of the first line and disposed in the bending area. A line width of the first line may be larger than a line width of the second line and a line width of the third line. The second line and the third line may be spaced apart from each other.

At least a portion of the first line may vertically overlap the first metal pattern. At least a portion of the second line and the third line may overlap the first metal pattern.

At least a portion of the first line vertically may overlap the first metal. The second line and the third line may not overlap the first metal.

The display device may further comprise a third insulation layer disposed on the second insulation layer. A thickness of the third insulation layer positioned in the bending area may be larger than a thickness of the third insulation layer overlapping the first insulation layer. The second insulation layer positioned in the bending area may be lower in height from the substrate than the second insulation layer overlapping the first insulation layer. The first metal pattern may be positioned to overlap the second insulation layer positioned in the bending area and the third insulation layer positioned in the bending area.

The display device may further comprise a second metal pattern disposed to extend farther outside than an end of the first insulation layer. The first metal pattern may be disposed to contact the second metal pattern and may be disposed farther outside than an end of the second metal pattern.

An edge portion of the first metal pattern may contact an upper surface of the substrate.

The display device may further comprise a first protective layer disposed to overlap the second metal, and an organic layer disposed on the first protective layer. The first metal pattern may be disposed to extend from a position overlapping the first protective layer and the second metal to the bending area.

The display device may further comprise a dam disposed outside the first protective layer. The first metal pattern may be disposed to overlap the dam in the bending area.

The display device may further comprise a second protective layer positioned outside the first protective layer or the organic layer and disposed to overlap the first metal pattern in the bending area, and a cured layer positioned on the second protective layer. In the bending area, the second protective layer and the cured layer together may be bent. The first metal pattern may be disposed to overlap the cured layer contractable or expandable.

Embodiments of the disclosure may provide a display device comprising a substrate, a display area, a non-display area positioned outside the display area and including a pad area and a bending area positioned closer to the display area than the pad area, a first insulation layer disposed on the substrate, a first metal pattern disposed on the first insulation layer and extending to at least a partial area in the bending area positioned farther outside than an edge of the first insulation layer, a second insulation layer disposed on the first metal pattern, and a line disposed on the second insulation layer and electrically connecting a pad in the pad area and the first metal pattern, wherein the second insulation layer may include a contact hole for electrically connecting the line and the first metal pattern, and wherein the contact hole may be positioned in the display area or positioned closer to the display area than the bending area in the non-display area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure. The scope of protection of the present disclosure should be construed based on the following claims, and all technical features within the scope of equivalents thereof should be construed as being included within the scope of the present disclosure.

What is claimed:

1. A display device, comprising:
a substrate;
a display area;
a non-display area positioned outside the display area and including a bending area;
a first metal disposed on the substrate and positioned in the display area or positioned closer to the display area than the bending area in the non-display area;
a first insulation layer disposed on the first metal and extending farther to the bending area than the first metal; and
a first metal pattern disposed on the first insulation layer, electrically connected to the first metal, and extending through a side surface of the first insulation layer to the bending area.

2. The display device of claim 1, further comprising: at least one support substrate stronger than the substrate disposed under a partial area of the substrate.

3. The display device of claim 1, further comprising:
a second metal disposed on the first insulation layer and electrically connected to the first metal pattern; and
an interlayer insulation layer on the second metal,
wherein the first metal pattern is disposed on the interlayer insulation layer,
wherein at least a portion of the first metal pattern overlaps the second metal, and
wherein the first metal pattern includes:
a first connection portion connected to the second metal through a contact hole of the interlayer insulation layer; and
a second connection portion connected to the first metal through a contact hole of the first insulation layer and a contact hole of the interlayer insulation layer.

4. The display device of claim 3, wherein the first metal is parallel to the second metal.

5. The display device of claim 3, wherein the first metal pattern further includes an extension extending from the first connection portion toward the display area.

6. The display device of claim 5, wherein the extension is parallel to the first metal and the second metal.

7. The display device of claim 3, further comprising a first transistor disposed in the display area on the substrate, and including a first active layer, a first gate electrode, a first source electrode, and a first drain electrode,
wherein the first metal includes a same material as a material of the first gate electrode of the first transistor, and
wherein the first metal pattern includes a material different from the first metal.

8. The display device of claim 7, further comprising a second transistor disposed in the display area on the substrate, and including a second active layer, a second gate electrode, a second source electrode, and a second drain electrode,
wherein the first metal pattern includes a same material as a material of the second gate electrode of the second transistor.

9. The display device of claim 8, wherein the second active layer is farther away from the substrate than the first active layer, and
wherein the first active layer and the second active layer include different semiconductor materials.

10. The display device of claim 1, further comprising:
a second insulation layer disposed on the first metal pattern; and
a metal line on the second insulation layer,
wherein the second insulation layer includes a first contact hole for electrically connecting the metal line and the first metal pattern,
wherein the metal line extends from a point where the first contact hole is located in a direction from the display area to the bending area, and
wherein the first contact hole is positioned between the display area and the bending area.

11. The display device of claim 10, further comprising a connection pattern disposed between the first metal pattern and the second insulation layer,
wherein the metal line is connected to the connection pattern through the first contact hole, and the connection pattern is connected to the first metal pattern.

12. The display device of claim 11, wherein the connection pattern includes a same material as a material of a source or drain electrode of a second transistor disposed in the display area, and
wherein the first metal pattern includes a same material as a gate electrode of the second transistor.

13. The display device of claim 11, wherein the second insulation layer further includes a second contact hole for electrically connecting the metal line and the first metal pattern, and wherein the second contact hole is positioned closer to the display area than the first contact hole.

14. The display device of claim 13, wherein in a width direction of the metal line, the first contact hole includes a plurality of first contact holes, and the second contact hole includes a plurality of second contact holes.

15. The display device of claim 10, wherein the metal line includes:
a first line disposed in a link area between the display area and the bending area;
a second line extending from a portion of the first line and disposed in the bending area; and
a third line extending from another portion of the first line and disposed in the bending area,
wherein a line width of the first line is larger than each of a line width of the second line and a line width of the third line, and
wherein the second line and the third line are spaced apart from each other.

16. The display device of claim 15, wherein at least a portion of the first line vertically overlaps the first metal pattern, and
wherein at least a portion of the second line and the third line overlaps the first metal pattern.

17. The display device of claim 15, wherein at least a portion of the first line vertically overlaps the first metal, and
wherein the second line and the third line do not overlap the first metal.

18. The display device of claim 10, further comprising a third insulation layer disposed on the second insulation layer,
wherein a thickness of the third insulation layer positioned in the bending area is larger than a thickness of the third insulation layer overlapping the first insulation layer,
wherein a lower surface of the second insulation layer positioned in the bending area is lower in height from the substrate than a lower surface of the second insulation layer overlapping the first insulation layer, and
wherein the first metal pattern overlaps the second insulation layer positioned in the bending area and the third insulation layer positioned in the bending area.

19. The display device of claim 1, wherein an edge portion of the first metal pattern contacts an upper surface of the substrate.

20. A display device, comprising:
a substrate;
a display area;
a non-display area positioned outside the display area and including a pad area and a bending area positioned closer to the display area than the pad area;
a first insulation layer disposed on the substrate;
a first metal pattern disposed on the first insulation layer and extending to at least a partial area in the bending area positioned farther to the bending area than an edge of the first insulation layer;
a second insulation layer disposed on the first metal pattern; and
a line disposed on the second insulation layer and electrically connecting a pad in the pad area and the first metal pattern,
wherein the second insulation layer includes a contact hole for electrically connecting the line and the first metal pattern, and
wherein the contact hole is positioned in the display area or positioned closer to the display area than the bending area in the non-display area.
